(19) United States
(12) Patent Application Publication
(10) Pub. No.: US 2006/0087707 A1
(43) Pub. Date: Apr. 27, 2006

(54) Image taking apparatus

(75) Inventor: Kazuki Akaho, Sakai-shi (JP)

Correspondence Address: SIDLEY AUSTIN LLP, 717 NORTH HARWOOD, SUITE 3400, DALLAS, TX, 75201, US

(73) Assignee: KONICA MINOLTA PHOTO IMAGING, INC.

(21) Appl. No.: 11/070,526

(22) Filed: Mar. 2, 2005

(30) Foreign Application Priority Data
Oct. 25, 2004 (JP) 2004-309975

(51) Int. Cl. G03F 3/08

(52) U.S. Cl. 358/518

(57) ABSTRACT

An image taking apparatus is provided with a CCD array, a shake correcting unit for correcting a relative displacement of an optical axis of a taking lens and the CCD array resulting from a shake, a CCD position controlling table for detecting a relative position of the optical axis and the CCD array, a memory for storing an arrangement pattern on comparison points beforehand, a color shading correction data table memory for storing color shading correction information patterns of the respective colors at the respective comparison points of the arrangement pattern, a color shading correction data setting section for setting a color shading correction information pattern at the comparison point close to the relative position through the comparison of the relative position with the respective comparison points, and an image processor for carrying out color shading corrections to a photographed image in accordance with the newly set color shading correction information pattern. A color shading correction can be carried out to asymmetric and complicated color shading, and precise color shading corrections can be carried out in such a photographing operation as to correct a shake such as a camera shake.

This application is based on patent application No. 2004-309975 filed in Japan, the contents of which are hereby incorporated by references.

### BACKGROUND OF THE INVENTION

The present invention relates to an image taking apparatus such as an electronic camera and particularly to an image taking apparatus having a shake correcting function and capable of a shading correction.

Conventionally, an image taking apparatus such as an electronic camera is provided with an image sensor including, for example, CCDs (charge coupled devices), whereby an object light incident from a taking lens is sensed to obtain a photographed image. This photographed image may have a density (brightness) variation due to the heterogeneity of the sensitivity of the image sensor and the illuminance of a light source or a reduction in the illuminance of a peripheral portion in a minification optical system, i.e., a reduction in an amount of light in the peripheral portion relative to an optical axis center of the object light caused by the taking lens and its diaphragm (aperture value). Accordingly, a so-called shading correction (sensitivity correction) is carried out to prevent the shading by changing gains (amplification factors) for the respective image sensing elements or (at the respective pixel positions) constructing the image sensor to correct the reduction in the amount of light. This shading correction is referred to as a “luminance shading correction” in order to distinguish it from a color shading correction to be described later.

FIG. 14 shows one example of a general luminance shading correcting circuit. In a luminance shading correcting circuit 600 in FIG. 14, image data and luminance shading correction table are respectively saved in storage areas 602, 603 of a memory 601. These image data and the luminance shading correction table are sent to a multiplying circuit 607 of a luminance shading correction block 606 by DMA controllers 604, 605 (by way of FIFO buffers of channels N1, N2). Data relating to the gains or gain data are written in the luminance shading correction tables, and the gain data corresponding to the respective pixel data in the image data are successively or synchronously multiplied for the respective pixel data by the multiplying circuit 607. The image data converted by the luminance shading correction are successively transmitted to and saved in a storage area 609 by a DMA controller 608 or by way of a FIFO buffer of a channel N3. By multiplying the respective pixel data of the sensed image by arbitrary gains using such a luminance shading correcting circuit 600, a luminance shading correction is carried out to avoid the density (brightness) variation.

Regarding this shading, a phenomenon of differing shading amounts for the respective colors R, G, B as the image sensor is miniaturized, following the required miniaturization of the electronic camera, so-called color shading, has been conspicuously seen in recent years. In order to deal with this problem of color shading, a color shading correction is applied to the respective pixel data in accordance with shading correction coefficients corresponding to the respective colors of a color filter, for example, according to a technology disclosed in Japanese Unexamined Patent Publication No. 2002-218298.

With the miniaturization of the electronic camera or (image sensor), the camera has come to possess not only telecentric optical systems as in the prior art, but also optical systems having a finite exit pupil. Further, in order not only to miniaturize the image sensor, but also to meet a request for high image quality, a microlens (light gathering lens) is provided for each pixel such as a pixel 701 to efficiently gather the light as shown in FIG. 15 showing a pixel section 700 and an incident state of a light on the pixel (in FIG. 15, larger and smaller microlenses 703, 704 are, for example, provided before and after a color filter 702 of R for the pixel 701). The exit pupil tends to become even smaller due to the easiness of its design, the respective microlenses shrunk based on an exit pupil position (pupil correction) are, for example, used as shown in FIG. 16.

As shown in a construction of the image sensor of FIGS. 17 and 18 (FIG. 17 shows one end of the image sensor and FIG. 18 shows the other end of the image sensor), an amount of light (exposure amount) obtained in each image sensing element differs depending on the color because of the transversely asymmetric arrangement of the respective image sensing elements of the image sensor with respect to an optical axis center, dispersion in the microlenses at the exit pupil positions or a problem in the construction of the image sensing elements (insufficient light shielding of the image sensor resulting from the miniaturization. Thus, in the case that an attempt is made to carry out a color shading correction, it is necessary to multiply outputs of each colors R, G, B by different gains vertically and transversely asymmetric (gain curve). Further, there is a strong demand to miniaturize the taking lens, and the color shading is largely influenced due to errors at the time of assembling, i.e., production errors such as displacements of an electrode structure and a light shielding portion in the image sensing element. In the case of considering the image sensor and the lens in pair, occurring color shading is asymmetric and complicated.

Some electronic cameras of recent years are provided with a shake correcting function for correcting a shake such as a camera shake, and a relative positional relationship of a taking lens (optical lens) and an image sensor (image sensing elements) changes according to a shake at the time of a shake correction. The color shading differs due to the change of the relative positional relationship of the taking lens and the image sensor.

According to the technology disclosed in Japanese Unexamined Patent Publication No. 2002-218298, the shading correction is carried out using such shading correction coefficients (equivalent to the gains) as to carry out the shading correction in quasi-concentric circles. Thus, it is difficult to apply this technology to the asymmetric and complicated color shading. Further, this publication does not disclose the color shading in the case of carrying out the above shake correction.

### SUMMARY OF THE INVENTION

It is an object of the present invention to provide an image taking apparatus which is free from the problems residing in the prior art.

It is another object of the present invention to provide an image taking apparatus which is able to correct asymmetric and complicated color shading or color shading correction, and precisely carry out the color shading correction when correcting a shake.

According to an aspect of the present invention, an image taking apparatus is provided with an image sensor to be exposed to an object light image passed through a taking lens to obtain a photographed image, a shake corrector for correcting a displacement of an optical axis of the taking lens against the image sensor caused by a shake, a position detector for detecting a relative position between the optical axis and the image sensor as a result of the movement, a storage device for storing color shading correction information patterns used for color shading corrections of the photographed image, and a color shading corrector for carrying out color shading corrections to the photographed image in accordance with the relative position detected by the position detector.

These and other objects, features and advantages of the present invention will become more apparent upon a reading of the following detailed description and accompanying drawings.

### BRIEF DESCRIPTION OF THE DRAWINGS

FIG. 1A is a perspective view showing an external configuration of an electronic camera embodying the present invention;

FIG. 1B is a rear view of the electronic camera shown in FIG. 1A;

FIG. 2 is a block diagram showing an electrical construction of the electronic camera shown in FIG. 1,

FIG. 3 is a diagram showing a relative displacement of a taking lens and a CCD array caused by a shake of the electronic camera;

FIG. 4 is a schematic section showing a construction of the CCD array and a CCD position controlling table;

FIG. 5 is a block diagram showing a construction for realizing a camera shake correcting function of the electronic camera;

FIG. 6 is a diagram showing an arrangement pattern of comparison points to be compared with a relative position of an optical axis of the taking lens and an image sensor;

FIG. 7 is a conceptual diagram showing gain data in a shading correction table and an inner interpolation based on the gain data;

FIG. 8 is a block diagram showing a construction for realizing a color shading correction of the electronic camera;

FIG. 9 is a chart showing detection of position information during each exposure period of the CCD array;

FIG. 10 is a diagram showing detection of position information during each exposure period of the CCD array and operations concerning the color shaking correction based on this detection;

FIG. 11 is a flowchart showing a flow of operations concerning the color shading correction of the electronic camera according to this embodiment;

FIG. 12 is a diagram showing a modification of a color arrangement pattern shown in FIG. 6;

FIG. 13 is a diagram showing another modification of the color arrangement pattern shown in FIG. 6;

FIG. 14 is a block diagram showing a conventional circuit construction for a shading correction;

FIG. 15 is a diagram showing a cross section of conventional pixels and an incident state of a light on the pixel;

FIG. 16 is a schematic construction diagram of an image sensor showing a conventional lens shrinking technology; and

FIGS. 17 and 18 are sections of pixels showing a transversely asymmetric construction of a conventional image sensor.

### DETAILED DESCRIPTION OF THE PREFERRED EMBODIMETNS OF THE INVENTION

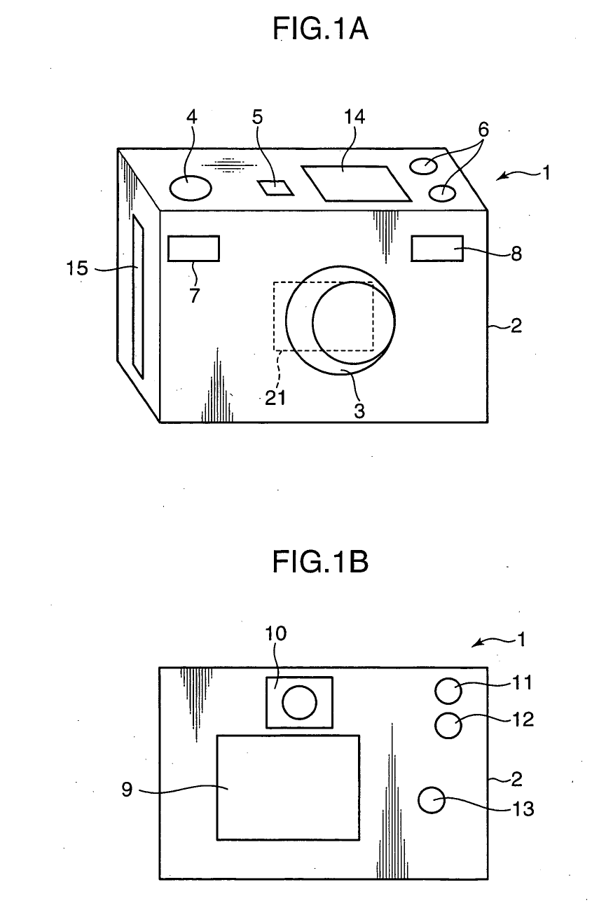

Referring to FIGS. 1A and 1B showing an external configuration of an electronic camera 1 in accordance with an embodiment of the present invention, the electronic camera 1 is provided with a camera main body 2 and a taking lens 3 arranged at one end side of the camera main body 2. A release button 4, a power switch or main switch 5 and mode setting keys 6 are arranged on a top surface of the camera main body 2, and a flash device 7 and a distance metering window 8 are arranged on the front surface thereof in addition to the taking lens 3. An LCD monitor 9, an electronic viewfinder 10, and various operation keys, switches, and buttons such as a photographing/reproducing selection key 11, an information display setting changeover key 12 and a camera shake preventing function setting key 13.

The taking lens 3 functions as a lens window for introducing an object light (light image) and constructs an optical lens system including a zoom lens block and a fixed lens block serially arranged along an optical axis of the taking lens for introducing the object light to a CCD Array 21 to be described later disposed inside the camera main body 2.

The release button 4 is for starting a photographing operation. When the release button 4 is pressed down, a series of photographing operations including the picking-up of the object light by means of the CCD array 21, application of a specified image processing to the thus obtained image data, and the succeeding recordation of the processed image data in a specified recording section are carried out. The power switch 5 is for turning the electronic camera 1 on and off. The mode setting keys 6 are for setting exposure conditions including an aperture priority mode and a shutter-speed priority mode for automatic exposure control (AE control); for switching photographing modes including a still image photographing mode, a moving image photographing mode (continuous photographing mode) and a photographing mode in which an automatic focusing control (AF control) is executed; and for switching or setting various modes including a live view mode in which a photographed image is displayed in real time and a reproduction mode in which a photographed image recorded in an image memory 110 to be described later is reproduced and displayed. The mode setting keys 6 may be caused to also function as zoom setting keys for switching a macrophotography mode and for changing a focal length of a zoom lens of the taking lens 3. Information set through the mode setting keys 6 and the like, various pieces of set information such as the number of photographed images and date information may be displayed on a display panel 14, including a liquid crystal panel, provided on the upper surface of the camera main body 2.

The flash device 7 is fired to emit a flash of light during flash photographing. The distance metering window 8 is the so-called AF sensor including distance metering elements for detecting in-focus information of an object. The LCD monitor 9 is a liquid crystal display (LCD) including color liquid crystal display elements, and adapted to display an image for live-view display (live-view image), a preview image for confirming the photographed image by pressing the release button 4, or a photographed image recorded in a memory card (or image memory) as a reproduced image. The electronic viewfinder (EVF) 10 is a liquid crystal screen formed in a small window of an eyepiece section and functions as a finder (viewing window) for displaying a video image captured by the CCD array 21.

The photographing/reproducing selection key 11 is turned on and off to select the photographing mode or the reproducing mode. If the photographing/reproducing selection key 11 is on, photographed images recorded in the image memory 110 or the like are reproduced and displayed on the LCD monitor 9 or the electronic viewfinder 10. If the photographing/reproducing selection key 11 is off, the photographing operation is carried out in the photographing mode set through the mode setting key 6. The information display setting changeover key 12 is for switching a display mode (display setting) of the information displayed on the LCD monitor 9. For example, the information display setting changeover key 12 is operated to display reproduced images as an index image in which a plurality of thumbnail images are arrayed, to make a selection display of frames to be reproduced, and to display images by frame advance on the LCD monitor 9. The camera shake preventing function setting key 13 is for turning on and off a shake preventing function (shake correcting function) for enabling secure photographing in the case that a shake such as a camera shake is likely to occur during hand-holding photographing, telescopic photographing, and photographing in the dark (requiring a long exposure).

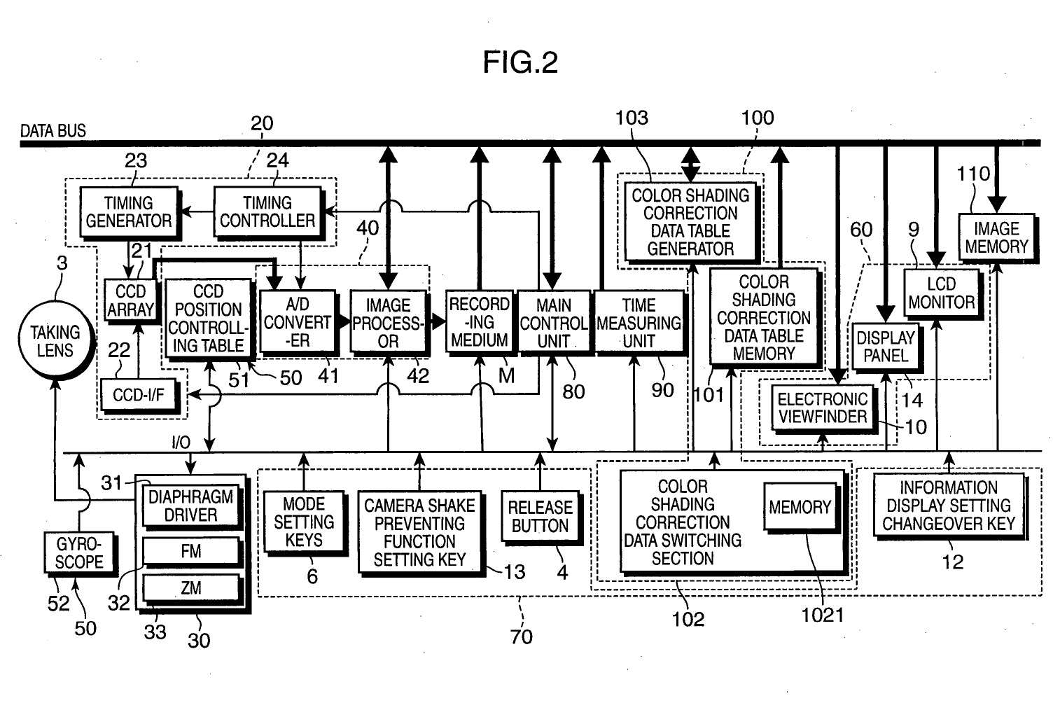

Various devices including the CCD array 21 for picking up an object light from the taking lens 3, a loudspeaker for outputting various sound effects, a battery chamber for accommodating a battery and a recording medium M in FIG. 2 such as a memory card as a recording medium are arranged inside the camera main body 2, wherein the recording medium is detachably mounted through a slot 15 serving as an insertion opening formed in a side surface of the camera main body 2. The camera main body 2 may also be provided with connector portions for an AV output terminal and a USB terminal as interfaces with external apparatuses, and a jack for an AC power supply. In addition to the respective switches, keys, and buttons described above, a monitor enlarging switch for enlargedly displaying an arbitrary area of an image displayed on the LCD monitor 9 or the electronic viewfinder 10 to operate as an electronic magnifier, a display changeover switch for switching the image display between the LCD monitor 9 and the electronic viewfinder 10 and the like may be provided.

Referring to FIG. 2 showing an electrical construction of the electronic camera 1 shown in FIG. 1, this electronic camera 1 is provided with the taking lens 3, an image sensing unit 20, a lens driving unit 30, a signal processing unit 40, a shake correcting unit 50, a display unit 60, an operation unit 70, a main control unit 80, and a time measuring unit 90, a shading correction information processing unit 100 and the image memory 110, etc. The taking lens 3 includes the optical lens system, e.g., focusing lens, zoom lens, and a diaphragm for adjusting an amount of transmitting light, and is so constructed as to execute focusing and zooming by automatically moving the positions of the respective lenses. The image sensing unit 20 is for photoelectrically converting the object light image incident through the taking lens 3 and outputting the resultant as image signals, and includes the CCD array 21, a CCD interface 22, a timing generator 23, and a timing controller 24.

The CCD array 21 picks up the object light to detect an object luminance, i.e., photoelectrically converts image signals of the respective color components R, G, B in accordance with a light amount of the object light image focused by the taking lens 3 and outputs the resulting image signals to the signal processing unit 40 via a specified buffer. Specifically, the CCD array 21 is a color image sensor constructing a single-plate color area sensor of so-called Bayer system in which primary-color transmitting filters (color filters) of R (red), G (green) and B (blue) are adhered in a checkerwise manner pixel by pixel to the outer surfaces of two-dimensionally arrayed CCDs (charge-coupled devices) of an area sensor. The image sensor may be selected from a CCD image sensor, a CMOS image sensor, a VMIS image sensor and the like. In this embodiment, a CCD image sensor is used.

The CCD interface 22 controllably drives the CCD array 21 including photoelectric conversion elements in accordance with a control signal inputted from the main control unit 80. The CCD interface 22 generates drive control signals (accumulation start signal, accumulation end signal) for the CCD array 21 in accordance with a drive timing pulse from the timing generator 23, generates readout control signals (horizontal synchronizing signal, vertical synchronizing signal, transfer signal, etc.) by the so-called interlacing, and sends the respective generated signals to the CCD array 21. The CCD interface 22 applies an analog processing such as a gain (amplitude) change to the output signals from the CCD array 21 in accordance with the readout control signals, and sends them to the signal processing unit 40.

The timing generator 23 generates the drive timing pulse in accordance with a reference clock signal inputted from the timing controller 24. The timing controller 24 generates the reference clock signal to be given to the timing generator 23 in accordance with a control signal inputted from the main control unit 80. The timing controller 24 generates a timing signal (reference clock signal) used for processing the image signals sent out from the CCD array 21 in the signal processing unit 40, and outputs this timing signal to an analog-to-digital (A/D) converter 41 and the like in the signal processing unit 40 to be described later.

The image sensing unit 20 executes a feedback control so that an exposure period (accumulation period of the object light by the image sensor; integration period) of the CCD array 21 is proper. Specifically, an aperture value for a diaphragm is fixed by a later-described diaphragm driver 31 of the lens driving unit 30, for example, in the live view mode at the time of photographing. In this state, a light measurement (divided light measurement, etc.) for an object by the CCD array 21 is carried out. Parameters for the exposure control (parameter for the exposure amount control and parameter for the dynamic range control) are calculated based on the light measurement data (evaluated value) in the main control unit 80, and parameters for the feedback control are calculated in accordance with the parameters for the exposure control and a program diagram, e.g., photoelectric conversion characteristic diagram of the CCD 21, set beforehand. The CCD array 21 is feedback-controlled in accordance with these parameters for the feedback control by the CCD interface 22 and the timing generator 23. However, this diaphragm also functions as a shutter, and the exposure amount made to the CCD array 21 is controlled by controlling an aperture area of the diaphragm by the diaphragm driver 31 based on the parameters for the feedback control at the time of carrying out substantial photographing.

The lens driving unit 30 controls the operations of the respective elements of the taking lens 3, and includes the diaphragm driver 31, a focusing lens driving motor (hereinafter, “FM”) 32 and a zoom lens driving motor (hereinafter, “ZM”) 33. The diaphragm driver 31 controls the aperture value of the diaphragm, and drives the diaphragm in accordance with information on the aperture value inputted from the main control unit 80 to adjust the aperture amount of the diaphragm. The FM 32 drives the focusing lens in accordance with an AF control signal, e.g., control value such as a drive pulse number, inputted from the main controller 80 to move the focusing lens to a focusing position. The ZM 33 drives the zoom lens in accordance with a zoom control signal (zooming information given by way of the mode setting key 6) inputted from the main control unit 80 to move the zoom lens toward a telephoto side or a wide-angle side.

The signal processing unit 40 applies specified signal processings including analog signal processings and digital signal processings to an image signal sent out from the CCD array 21. The signal processing unit 40 includes the A/D converter 41 and an image processor 42. The A/D converter 41 converts an analog image signal having an analog value and sent from the CCD array 21 into a digital image signal having a digital value, wherein a pixel signal obtained by each pixel receiving the light is converted into a pixel data of, e.g., 12 bits.

The image processor 42 applies specified image processings (digital signal processings) to the image signal obtained through the A/D conversion by the A/D converter 41. The image processings executed here include, for example, pixel interpolation for interpolating (substituting) the respective pixel values using a specified filter; resolution conversion for converting the resolution to the set pixel number of the recorded image by reducing or skipping horizontal and vertical pixel data of the image data; white balance correction for correcting the white balance (WB) by adjusting the color balance of the respective colors R, G, B; shading correction for correcting the heterogeneity (color shading) of the respective colors R, G, B in the image; gamma correction for correcting the gradation by correcting a gamma (γ) characteristic of the image data; and image compression for compressing the image data.

The signal processing unit 40 may also be provided with a CDS (correlated double sampling) circuit for reducing a sampling noise of the image signal having an analog value and outputted from the CCD array 21, and a AGC (automatic gain control) circuit for adjusting the gain (level) of the image signal having an analog value and inputted from the CDS circuit.

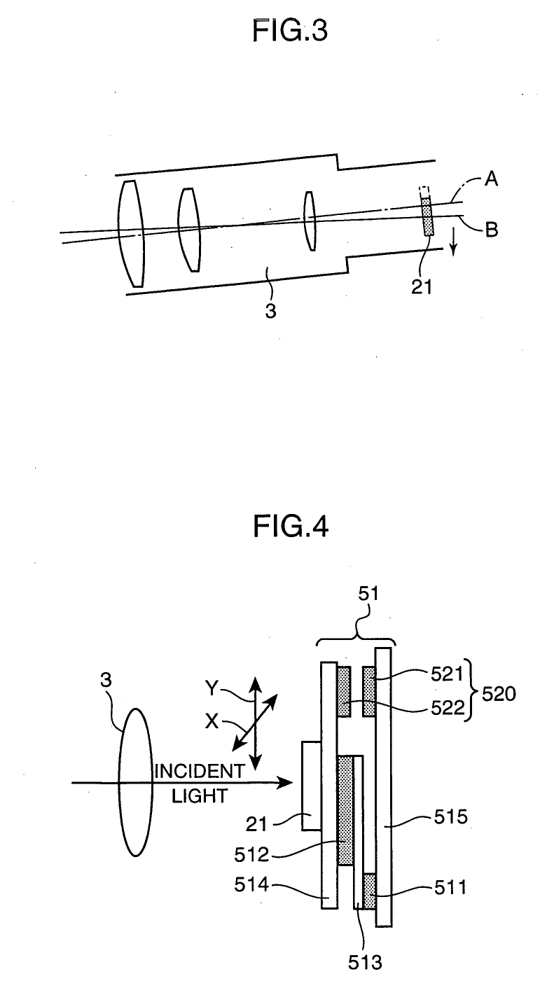

The shaking correcting unit 50 corrects a shake created as a result of a camera shake or the like. Specifically, if the camera shakes to displace the optical axis of the taking lens 3 from the line A to the line B with respect to the CCD array 21, for example, as shown in FIG. 3, the shake is corrected by shifting the CCD array 21 in accordance with this displacement of the optical axis. The shake correcting unit 50 includes a CCD position controlling table 51 and a gyroscope 52. The CCD position controlling table 51 includes at least two piezoelectric actuators of yaw direction and pitch direction, and controls or moves the position of the CCD array 21 relative to the optical axis by driving these piezoelectric actuators.

Specifically, the CCD position controlling table 51 is comprised of a yaw-direction piezoelectric actuator 511, a pitch-direction piezoelectric actuator 512, frame bodies 513, 514, a base portion 515 and a position detector 520 and the like, for example, as shown in FIG. 4. Each of the yaw-direction piezoelectric actuator 511 and the pitch-direction piezoelectric actuator 512 is an impact-type linear actuators (piezoelectric actuators) for executing a so-called supersonic drive, and includes a piezoelectric element which elongates and contracts at high speeds in accordance with an applied voltage, a rod driven by the piezoelectric element or slider frictionally moved by the driving (vibration) of the rod and a weight for efficiently transmitting the vibration (the respective elements are not shown). The yaw-direction piezoelectric actuator 511 is secured to the base portion 515 fixed to the camera main body 2, and the frame body 513 corresponding to the slider of the yaw-direction piezoelectric actuator 511 is slid along X-axis direction, e.g., transverse direction.

On the other hand, the pitch-direction piezoelectric actuator 512 is fixed to the frame body 513 and slides the frame body 514 corresponding to the slider of the pitch-direction piezoelectric actuator 512 along Y-axis direction (vertical direction) together with the CCD array 21 disposed on the frame body 514. With this construction, an integral assembly of the frame body 513, the pitch-direction piezoelectric actuator 512, the frame body 514 and the CCD array 21 is moved along X-axis direction by the yaw-direction piezoelectric actuator 511, and the frame body 514 and the CCD array 21 are moved along Y-axis direction by the pitch-direction piezoelectric actuator 512 moved along X-axis direction.

A two-dimensional PSD (position sensitive device) 521 and a two-dimensional infrared LED 522 as position detecting elements constructing the position detectors 520 are so disposed on the base portion 515 and the frame body 514 as to face each other, respectively. The position of the CCD array 21 moved along X-axis direction by the yaw-direction piezoelectric actuator 511 and the position thereof moved along Y-axis direction by the pitch-direction piezoelectric actuator 512 are detected by the PSD 521 and the infrared LED 522. The position of the CCD array 21 relative to the optical axis of the taking lens 3 is detected in accordance with the detected position information of the CCD 21.

The gyroscope 52 is for detecting shake information including a shaking direction and a shaking amount of the electronic camera 1, and serves as a shake detector). The gyroscope 52 includes a yaw-direction gyroscope (not shown) for detecting a shaking amount based on the angular velocity of the shake of the electronic camera 1 along yaw direction and a pitch-direction gyroscope (not shown) for detecting a shaking amount based on the angular velocity of the shake along pitch direction, and the shake information detected by the yaw-direction gyroscope and the pitch-direction gyroscope is inputted to the main control unit 80. As such a gyroscope may be used the one of such a type that a voltage is applied to a piezoelectric element to bring the piezoelectric element into a vibrating state, and a distortion resulting from a Coriolis force created when an angular velocity created by the rotary motion of the piezoelectric element acts is extracted as an electrical signal to detect the angular velocity.

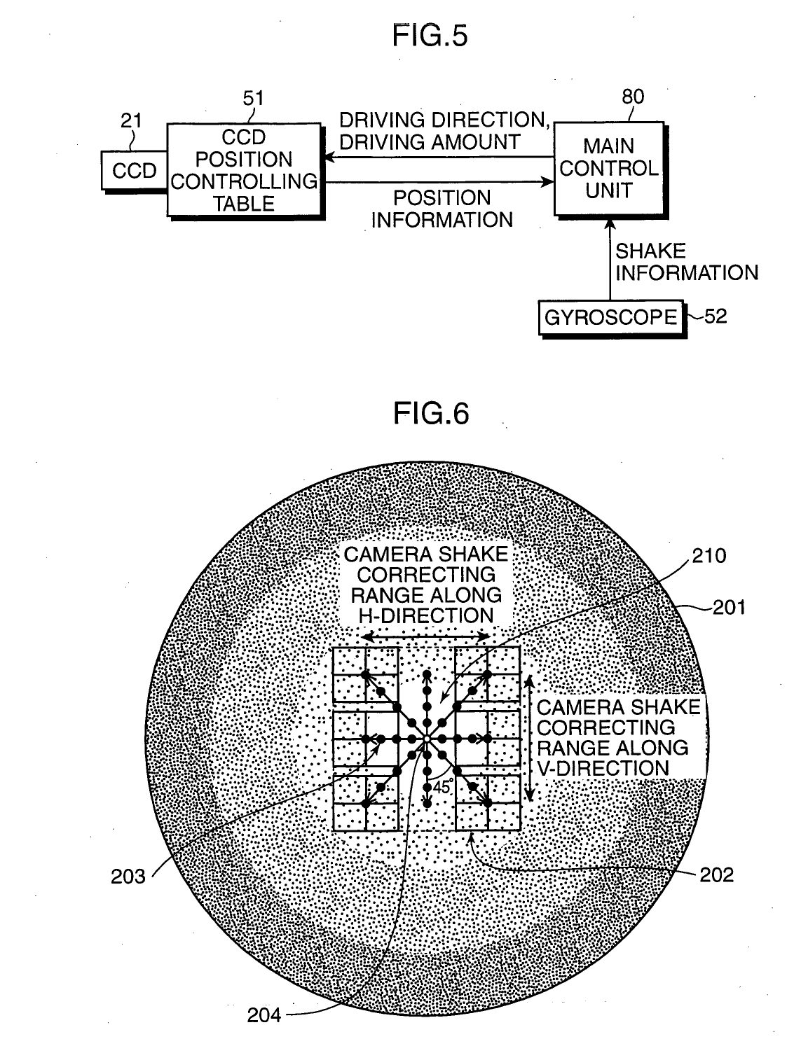

FIG. 5 shows a construction for realizing a camera shake correcting function of the electronic camera 1 using the CCD position controlling table 51 and the gyroscope 52, that is, the shake correcting unit 50. As shown in FIG. 5, the gyroscope 52 sends the detected shake information on the camera shake of the camera main body 2 to the main control unit 80, and the CCD position controlling table 51 sends the information on the current position of the CCD array 21 (corresponding to relative position information of the optical axis of the taking lens 3 and the CCD array 21 to be described later) detected by the position detector 520 to the main control unit 80. The main control unit 80 properly determines a driving direction and a driving amount of the CCD position controlling table 51 (CCD array 21) in order to reduce the influence of the shake) in accordance with the shake information and the position information, and causes the CCD position controlling table 51 (yaw-direction, pitch-direction piezoelectric actuators 511, 512) to be driven in accordance with drive control information based on the determined driving direction and driving amount. The position of the CCD array 21 in response to the shake of the electronic camera 1 is controlled or corrected by this construction.

The display unit 60 includes the LCD monitor 9, the electronic viewfinder 10 and the display panel 14, and displays a photographed image obtained by the CCD 21 (photographed image having the image processings applied thereto by the image processor 42 and saved in the image memory 110 or the recording medium M) and specified character information (characters and figures). The operation unit 70 includes various operation switches such as the release button 4, the mode setting keys 6 and the camera shake preventing function setting key 13, and is used to give instructions for various operations to the electronic camera 1. Operation information given by the operation unit 70 is outputted to the main control unit 80.

The main control unit 80 includes a ROM (read only memory) storing the respective control programs and the like, a RAM (random access memory) for temporarily saving data obtained by calculations and controls, and a CPU (central processing unit) for reading the control program or the like from the ROM and executing it, and centrally controls the photographing operation of the electronic camera 1. For example, upon detecting an operation signal representing that the release button 4 has been pressed halfway, the main control unit 80 causes the corresponding parts of the electronic camera 1 to carry out preparatory operations (setting of exposure control values, focusing, etc.) for photographing a still image of an object. Upon detecting an operation signal representing that the release button 4 has been fully pressed, the main control unit 80 causes the corresponding parts to execute the photographing operation, i.e., a series of operations including an exposure to the CCD array 21, application of image processings such as the shading correction to be described later to image signals obtained by the exposure, and saving of the image data in the image memory 110 or the recording medium M.

The time measuring unit 90 generates a clock signal (having a specified clock frequency) serving as a reference in the entire camera, and includes an oscillating element (not shown) such as a crystal oscillator as a clock generator. The clock signal generated in the time measuring unit 90 is outputted to the main control unit 80.

The image memory 110 is a memory for temporarily saving (storing) image data during the calculation in the image processor 42 and saving image data (image file) having the signal processing already applied thereto in the image processor 42, and has a capacity of saving image data of, for example, a plurality of frames. The image data in the image memory 110 are accessed and used in the respective units if necessary.

As shown in FIG. 2, the shading correction information processing unit 100 processes information on the color shading correction in this embodiment and includes a color shading correction data table memory 101, a color shading correction data setting section 102 and a color shading correction data table generator 103.

Color shading correction data tables of the respective colors R, G, B corresponding to a plurality of points (hereinafter, “comparison points”) to be compared with the relative position of the optical axis of the taking lens 3 and the CCD array 21, i.e., to be compared with the relative position on the CCD array 21 of the optical axis center of the object light incident from the taking lens 3 are stored in the color shading correction data table memory 101 beforehand. A plurality of comparison points have a specified arrangement pattern. First, this arrangement pattern of the comparison points is described.

FIG. 6 shows an arrangement pattern of the respective comparison points to be compared with the relative position of the optical axis of the taking lens 3 and the CCD array 21. In FIG. 6, a circle area identified by 201 represents a lens section of the taking lens 3 when viewed from the CCD array 21. A rectangular area identified by 202 represents a sensor surface of the CCD array 21 disposed in parallel with the lens surface of the taking lens 3 (assumed sensor surface in the case of assuming that the CCD array 21 is located at this position; hereinafter “assumed sensor surface 202”). Points at four corners (corner portions) of this assumed sensor surface serve as left, right, upper and lower limiting points (end or corner positions of the valid pixels) of the image sensing elements in the CCD array 21.

A plurality of black dots identified by 203 on the assumed sensor surface 202 and a white dot identified by 204 represent the comparison points, wherein the white dot is a reference position (relative position reference point) for the detection of the relative position of the optical axis of the taking lens 3 and the CCD array 21 and this comparison point serves as a reference point 204. As shown in an arrangement pattern 210 of FIG. 6, the respective comparison points are radially arranged from the reference point 204 as a center toward the peripheral four sides of the assumed sensor surface 202. Specifically, thirty two comparison points (black dots) are arranged on eight spread-out straight lines (angles between two adjacent ones of the straight lines extending in eight directions is 45°) in upward, downward, leftward, rightward, and oblique directions from the reference point 204 (white dot), and the comparison points are arranged at even intervals on each of these straight lines. Thus, the arrangement pattern 210 is formed by a total of thirty three comparison points (total number of the white dot and the black dots). The arrangement pattern 210 is a simple arrangement pattern of radially arranging the comparison points from the reference point 204 toward the peripheral sides at specified circumferential intervals (in eight directions). This is an arrangement in conformity with a radial movement from the reference point 204 toward a peripheral side, i.e., a change or movement of the relative position during the actual drive to correct the shake. Thus, the position of the comparison point close to the relative position of the optical axis can be efficiently detected.

FIG. 6 shows a state where the optical axis of the taking lens 3 coincides with the position of the reference point 204. Here, this state is referred to as an initial relative position (initially set position) of the taking lens 3, i.e., the optical axis, and the CCD array 21 at the start of the shake correcting operation. In accordance with a movement of the CCD array 21 by the shake correcting drive, the position of the CCD array 21 relative to the taking lens 3 changes, whereby the position of the optical axis located at the initial relative position (reference point 204) shown in FIG. 6 is relatively moved to an arbitrary position in the assumed sensor surface 202. At which position (coordinate position) on the assumed sensor surface 202 the moved position of the optical axis is located, for example, relative to the reference point 204 can be detected based on the detection information obtained by the position detector 520 of the CCD position controlling table 51.

Thirty three color shading correction information patterns or color shading correction data tables corresponding to each color R, G, B at thirty three points, i.e., at the respective comparison points of the arrangement pattern 210 are stored in the color shading correction data table memory 101. In other words, thirty three patterns corresponding to the thirty three points are stored for each of the colors R, G, B, i.e., a total of ninety nine patterns of the color shading correction information are stored for the colors R, G, B.

Although thirty three comparison points are radially arranged in eight directions in the arrangement pattern-210, the number and the arrangement of the comparison points are not limited thereto and may be arbitrarily set in accordance with a required color shading correction precision and the like. The comparison points may not be arranged at even intervals on each straight line. For example, the closer the comparison point to the reference point 204, the narrower the interval to the adjacent comparison point. Conversely, the more distant the comparison point to the reference point 204, the wider the interval to the adjacent comparison point. This applies also to arrangement patterns 220, 230 to be described later. The number of extending directions of the straight lines radially spreading out from the reference point 204 is not limited to eight, and may be more, e.g., ten or sixteen directions as described later, or less, e.g., seven directions. Further, the angles between the adjacent straight lines may not be an equal angle of 45°. The respective comparison points may not need to be radially arranged, i.e., arranged on the straight lines extending in specified directions, and may be randomly arranged. By increasing the number of the comparison points and having more color shading correction data tables corresponding to more comparison points, a more precise color shading correction is possible. Conversely, if the number of the comparison points is reduced to reduce the number of the color shading correction data tables, a smaller amount of data is handled, thereby making data processing easier or enabling a faster calculation, and reducing a memory capacity for storing such data.

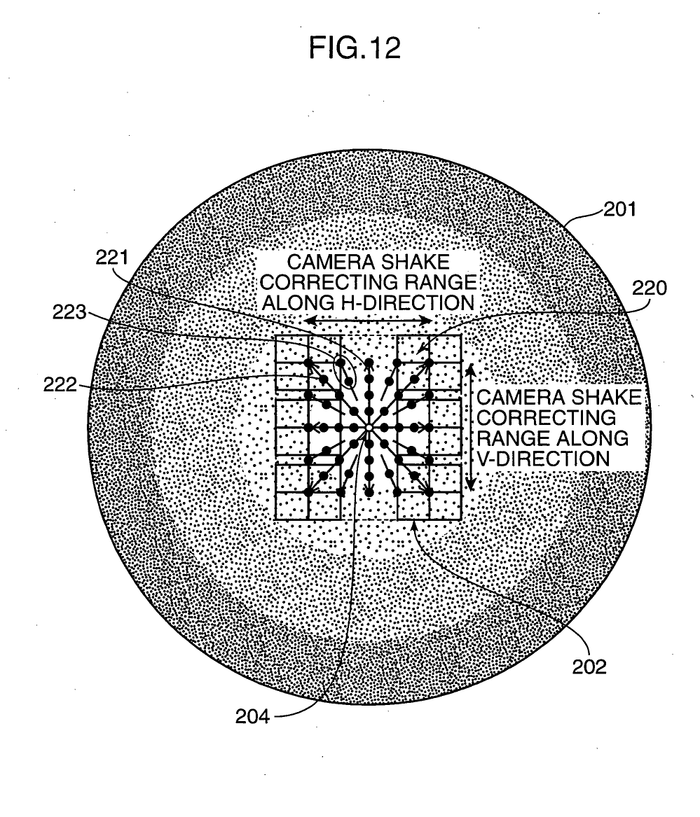

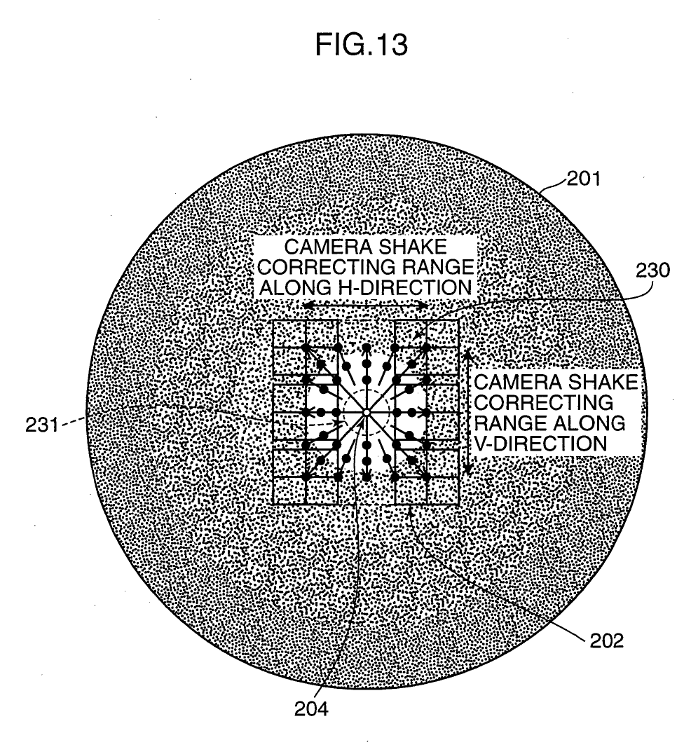

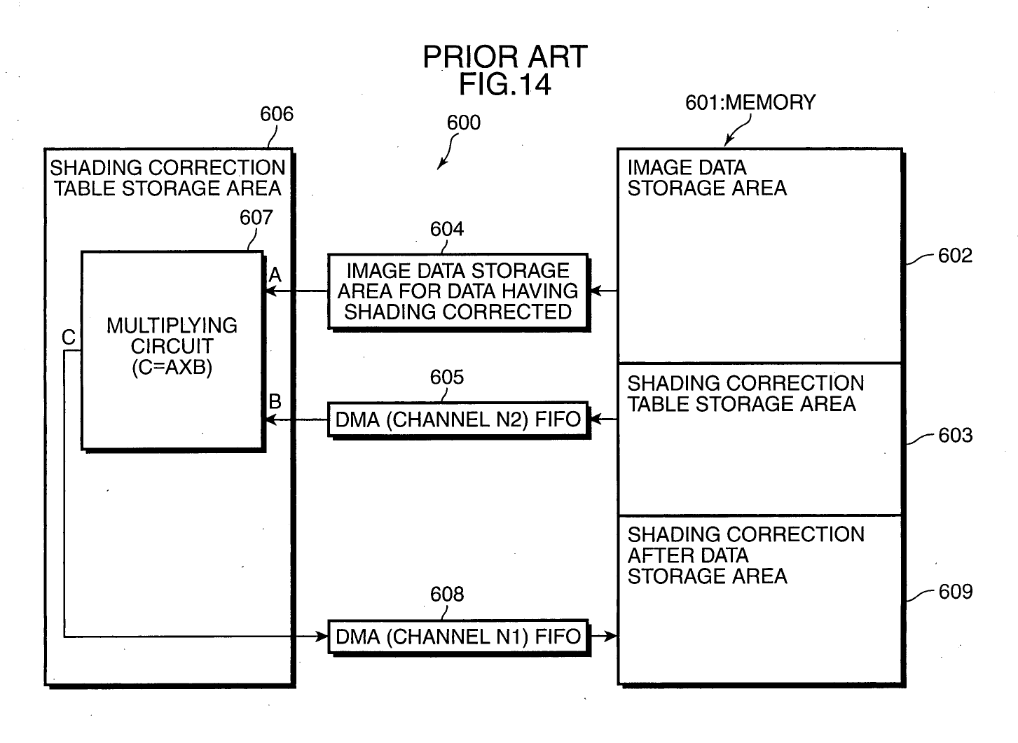

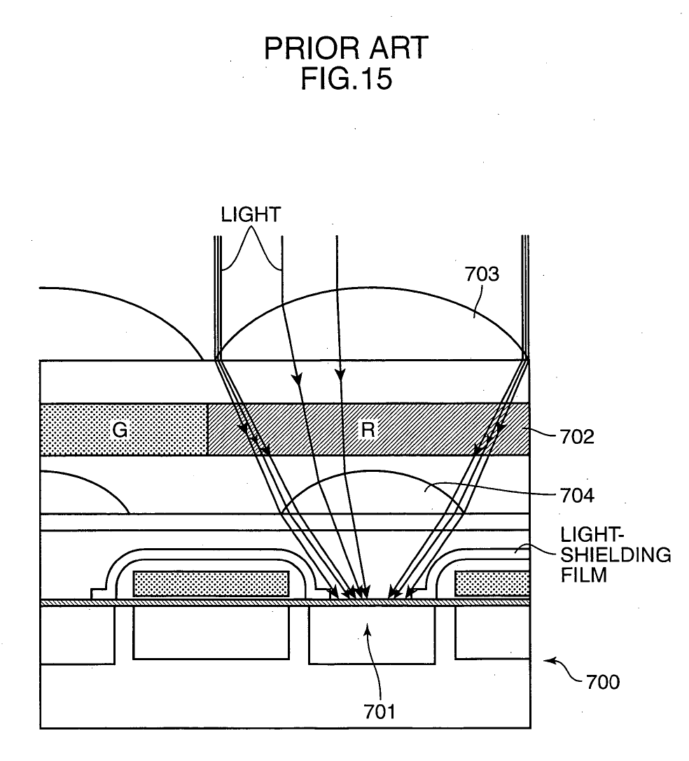

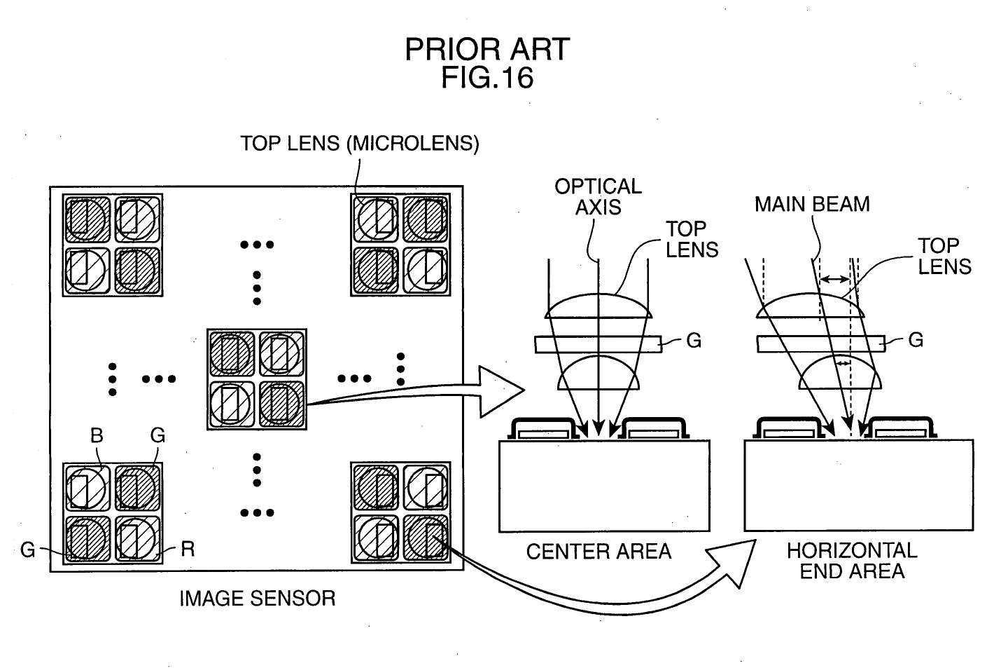

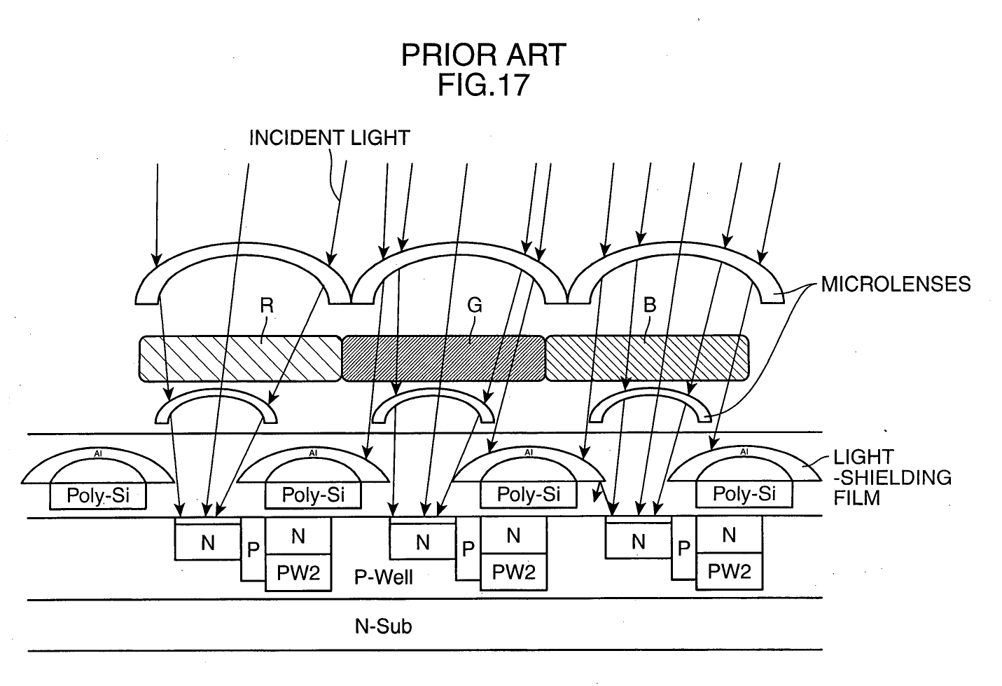

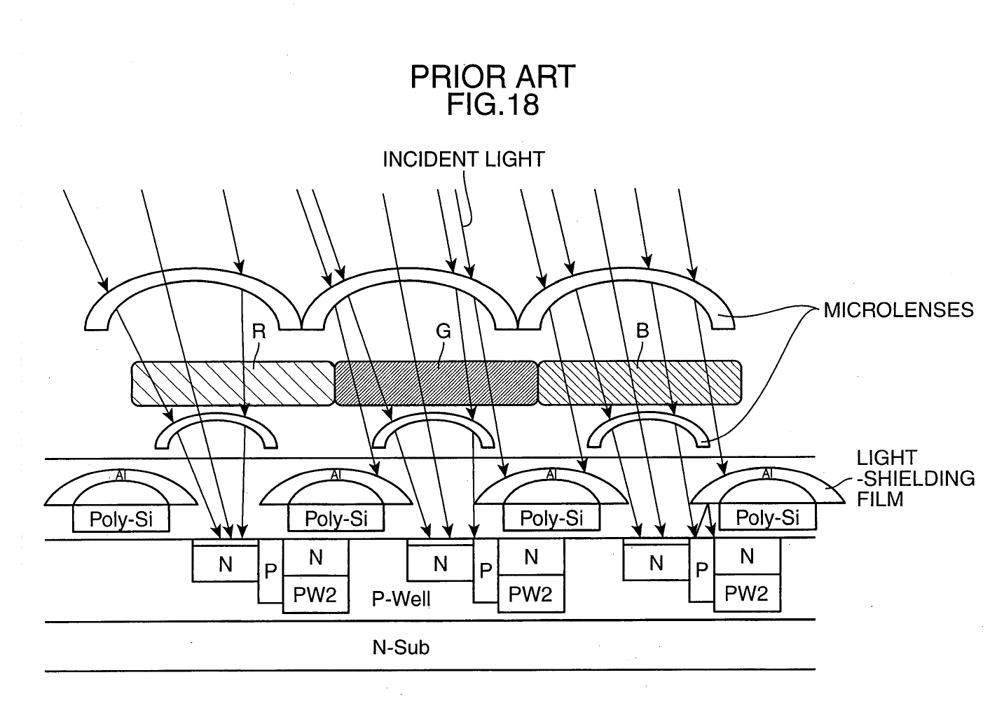

Arrangement patterns as shown in FIGS. 12 and 13 may, for example, be adopted as modifications of the arrangement pattern 210. In the arrangement pattern 220 shown in FIG. 12, the arrangement density of the comparison points in a peripheral area is made larger than or equal to that of the comparison points in a proximate area (range) to the reference point 204. Specifically, in the arrangement pattern 210 shown in FIG. 6, distances between adjacent comparison points are larger (intervals between adjacent comparison points are wider) as the comparison points are more distanced from the reference point 202 (center area) toward the peripheral sides of the assumed sensor surface 202, which can result in a rough color shading correction. Thus, such an arrangement pattern as to make the arrangement density of the comparison points in the peripheral area larger than or equal to that of the comparison points in the center area is adopted in order to possess more color shading correction data tables corresponding to the relative positions more distanced from the reference point 204.

Unlike the arrangement pattern 210 in which the straight lines spread out in eight directions, the comparison points are arranged on straight lines radially spreading out in sixteen directions by adding straight lines between those spreading out in eight directions in the arrangement pattern 220. Specifically, comparison points arranged on a straight line identified by 221 and comparison points arranged on a straight line identified by 222 correspond to those on the straight lines extending in eight directions in the arrangement pattern 210, and a straight line identified by 223 is added between these straight lines 221, 222, and other straight lines similar to the straight line 223 are similarly added over the entire circumference (added between two adjacent ones of the straight lines extending in eight directions), thereby forming an arrangement pattern of the comparison points spreading out in sixteen directions. However, as shown in FIG. 12, the comparison points on the added straight lines are set only at positions in and near the peripheral area (not arranged near the reference point 204). Thus, the arrangement density of the comparison point in the peripheral area is adjusted to be larger than or equal to that of the comparison points in the center area.

By adopting such an arrangement pattern 220, such color shading that the closer to the peripheral area, the larger a color shading amount or change, the steeper the gain curve, in other words, the closer to the peripheral area, the more comparison points (more color shading correction information patterns) are required can be precisely corrected.

The arrangement pattern 230 shown in FIG. 13 can be obtained by eliminating the comparison points in the proximate area or range to the reference point 204 from the arrangement pattern 220. If this area having no comparison point is referred to as a comparison-point free area 231, no color shading correction is carried out even if the relative position of the optical axis changes in this comparison-point free area 231. By adopting such an arrangement pattern 230, less arrangement pattern information is required and a memory capacity for storing it can be reduced. Further, the color shading correction is carried out in the peripheral area which is distanced from the proximate area to the reference point 204 (comparison-point free area 231) and where the influence of the color shading is not negligible, whereas no color shading correction is carried out in the specified range in the center where the influence of the color shading is negligible. Therefore, such an efficient color shading correction in conformity with color shading differences in the respective parts of a photographed image can be carried out. The comparison-point free area may be defined in the arrangement pattern 210 of FIG. 6 or in any arrangement pattern having arbitrarily set number and arrangement of the aforementioned comparison points.

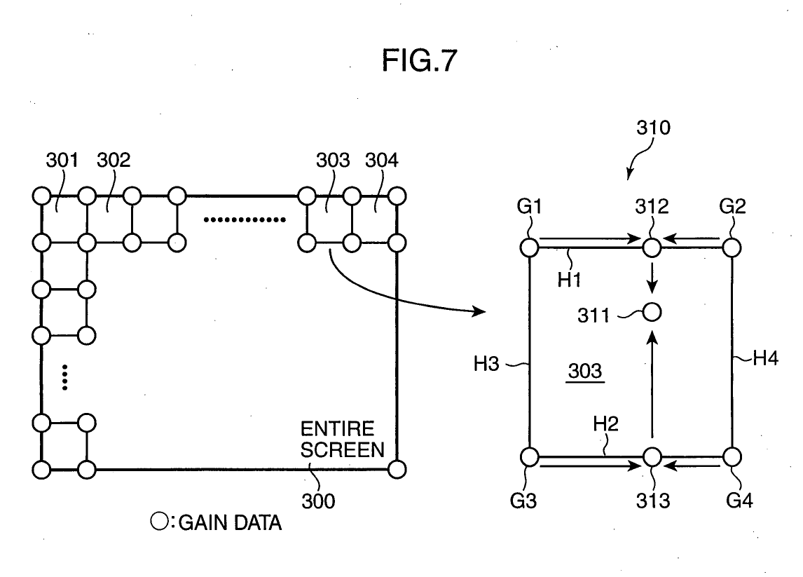

The shading correction tables saved in the color shading correction data table memory 101 are described in detail. FIG. 7 is a concept diagram showing gain data in the color shading correction data table and an inner interpolation based on the gain data. In FIG. 7, a screen 300 is the one corresponding to the photographed image obtained by the CCD array 21. It should be noted that this screen 300 is not the one actually displayed, but an assumed screen upon describing the gain data corresponding to the respective pixels. A specified point on this screen 300 represents a pixel point at a corresponding position on the photographed image.

The screen 300 is divided into a plurality of blocks 301, 302, 303, . . . For each of these blocks, gain data as a reference in obtaining a gain value for the respective pixels in each block (hereinafter, “reference gain data”) are set. Specifically, the reference gain data are gain values at pixel points (boundary pixel points) at boundaries between adjacent blocks (on boundary lines) and, here, are gain values at pixel points at the corners of each block (in other words, pixels at intersections of vertical and horizontal lines dividing the blocks as shown in FIG. 7). For example, shading correction table storage areas divided for the respective colors R, G, B are defined in the color shading correction data table memory 101, and the color shading correction data tables (gain tables) in which the reference gain data at the corner pixel points of the respective blocks are saved for the respective colors in the respective storage areas.

During the shading correction, the gain values of the respective colors corresponding to the respective pixels in the respective blocks are calculated based on the reference gain data by the inner interpolation through the inner interpolating function of the color shading correction data table generator 103 to be described later. This inner interpolation is described here. For example, as shown in an enlarged diagram of the block 303, reference gain data G1 to G4 denote the reference gain data corresponding to the pixel points at the corners of the block 303. In the case of obtaining a gain value corresponding to a certain pixel of the block 303, e.g., a pixel 311, a gain value corresponding to a pixel 312 on a side H1 between the reference gain data G1, G2 of the block 303 is first calculated by the inner interpolation using the reference gain data G1, G2, and a gain value corresponding to a pixel 313 on a side H2 between the reference gain data G3, G4 is similarly calculated by the inner interpolation using the reference gain data G3, G4. Subsequently, a gain value corresponding to the pixel 311 is calculated by the inner interpolation using the gain values corresponding to the pixels 312, 313. In this way, the gain data of the respective colors R, G. B are calculated at the respective coordinates of each block. However, a method for obtaining the gain value at each pixel point of each block by the inner interpolation is not limited to the above. For example, the gain value corresponding to the pixel 311 may be obtained by the inner interpolation after the gain values corresponding to the pixels on sides H3, H4 are calculated.

In this way, instead of having or saving the gain data corresponding to the photographed image for all the pixels of the image, it is sufficient to possess only the reference gain data of the respective colors for the inner interpolation for a plurality of blocks obtained by dividing this image like the screen 300. Thus, a memory capacity for saving the color shading correction information patterns (gain data; color shading correction data tables) can be reduced.

The respective sides H1 to H4 of each block may be treated as boundaries (boundary lines) between adjacent blocks. Although the side H1 of the block 303 is not a boundary to an adjacent block (side of the screen 300), sides (H1) that are actually no boundary to adjacent blocks are included in the “boundaries”.

The gain data at the pixel points at the corners and the sides of each block, i.e., the reference gain data of each block and the gain data obtained by the inner interpolation with respect to the pixel points on the respective sides may be treated, for example, as data corresponding to either one of the adjacent blocks or as data shared by both blocks. For example, in the block 303, the right side H4 and the reference gain data G2 at the corner may be treated as data (left side of the block 304 and the reference gain data at the pixel point at the left-upper corner) for the block 304 adjacent at the right side of the block 303 or as data shared by the block 304 (data corresponding to the block 303 and the block 304).

The color shading correction data setting section 102 sets a color shading correction information pattern at a comparison point close to the relative position based on the relative position information of the optical axis of the taking lens 3 and the CCD array 21 detected by the position detector 520 of the CCD position controlling table 51. Specifically, the color shading correction data setting section 102 has the arrangement pattern 210 (220, 230) saved, for example, in a memory 1021 provided therein and, upon receiving the relative position information from the position detector 520, compares the relative position with the respective comparison points in the arrangement pattern 210 to discriminate which comparison point is closest to the relative position. Based on this discrimination result, the color shading correction data setting section 102 sets the color shading correction information pattern corresponding to this comparison point.

Discrimination as to which comparison point is closest to the relative position is made, for example, by calculating distances between the coordinate position of the relative position and those of the respective comparison points on the assumed sensor surface 202 and determining the comparison point at the position having a shortest distance. However, if a plurality of comparison points are equidistant from the relative position, which comparison point is to be selected is set beforehand and determination is made based on this setting. In such a case, there may be, for example, determined such a specified order of priority as to prioritize the comparison point located at a clockwise position in the arrangement pattern 210 or to prioritize the comparison point in a certain area or on a certain line. Alternatively, all the equidistant comparison points may be used. In such a case, the color shading correction data tables corresponding to the equidistant comparison points may be added to the averaging of the color shading correction data tables (gain data) by the color shading correction data table generator 103 to be described later.

The color shading correction data table generator 103 generates or sets the color shading correction data table actually used for the color shading correction finally used in accordance with the color shading correction data tables read from the color shading correction data table memory 101 in response to a setting instruction from the color shading correction data setting section 102. Specifically, the color shading correction data table generator 103 has an averaging function of averaging the reference gain data (gain values) and the inner interpolating function of applying the inner interpolation using the reference gain data. The color shading correction data table generator 103 temporarily saves a plurality of color shading correction data tables (reference gain data) of the respective colors read from the color shading correction data table memory 101 and corresponding to the pertinent comparison points, and averages the reference gain data corresponding to the same pixel positions. Then, the color shading correction data table generator 103 generates an averaged color shading correction data table comprised of averaged gain data obtained by averaging the respective reference gain data, and further calculates the gain data corresponding to the respective pixels other than the average reference gain data by the inner interpolation of the inner interpolating function, thereby generating the color shading correction data tables (suitably called execution color shading correction data tables) actually used for the color shading correction.

The inner interpolation may be carried out only when the release button 4 is fully pressed to instruct the picking-up or recording of the photographed image (in this case, for example, for a live-view display image, no inner interpolation is carried out although the operations up to the averaging are carried out, and no shading correction is carried out). Alternatively, the inner interpolation may be carried out together with the averaging for all the photographed images including live-view display images and moving images regardless of whether or not an instruction to pick up or record the photographed image is given.

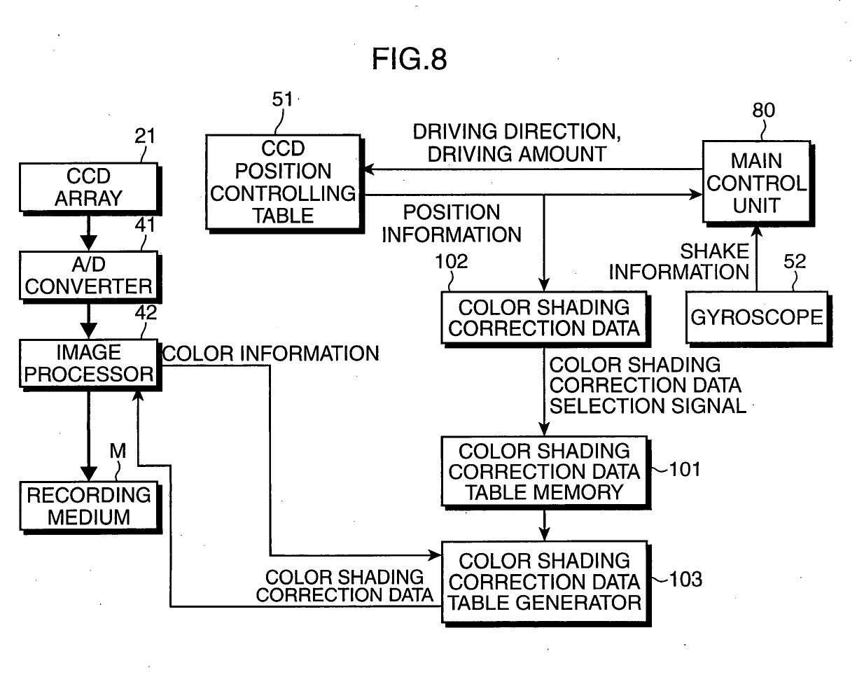

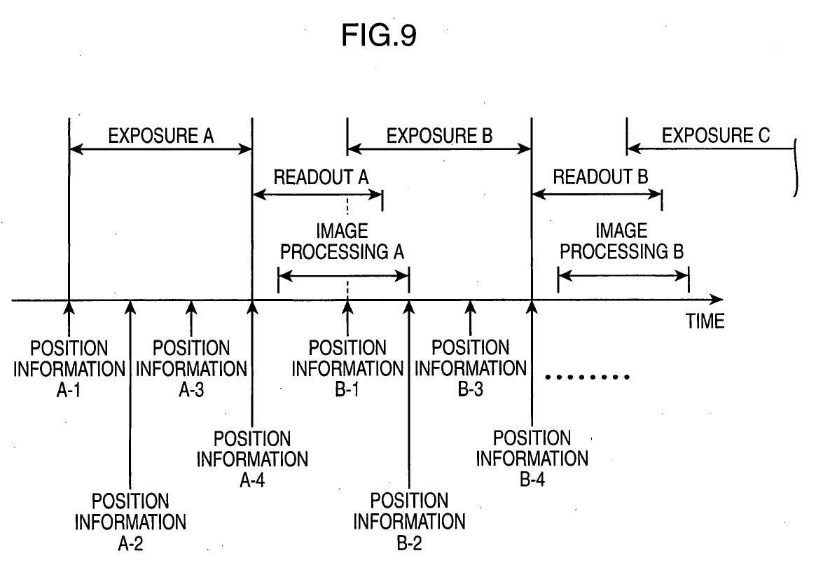

FIG. 8 shows a construction for realizing the color shading correction of the electronic camera 1 of this embodiment, using the shading correction information processing unit 100. In FIG. 8, when the exposure to the CCD array 21 by an object light is started, the shake information from the gyroscope 52 and the position information of the CCD array 21 (i.e., relative position information) from the CCD position controlling table 51 (position detector 520) are transmitted to the main control unit 80, which sends the drive control signal concerning the driving direction and driving amount of the CCD array 21 to the CCD position controlling table 51 for the shake correction control of the CCD array 21 in accordance with these pieces of information. The position information of the CCD array 21 is obtained by the CCD position controlling table 51 (position detector 520) at least once (here four times) during each exposure period (one exposure) of the CCD array 21. This is described with reference to FIG. 9. An exposure of a specified period corresponding to one frame of the photographed image is repeatedly made to the CCD array 21 such as exposures A, B, C. For each exposure period, for example, for the exposure A, there are given a readout period for the photographed image shown by READOUT A and a specified image processing (image processing A) period for the read image data. In this way, the exposure, the readout and the image processing are repeatedly carried during the photographing operation. Here, during each exposure period, for example, during the exposure A, four pieces A-1 to A-4 shown in FIG. 9 of the position information are detected at different timings. Likewise, four pieces B-1 to B-4 of the position information are detected at different timings during the next exposure B. The detection of such pieces of the position information are carried out for each exposure.

Every time the position information from the CCD position controlling table 51 is detected, it is sent to the color shading correction data setting section 102. Every time obtaining the position information from the CCD position controlling table 51, the color shading correction data setting section 102 executes such a control as to transfer the color shading correction data tables of the respective colors R, G, B suitable for the obtained position information from the color shading correction data table memory 101 to the color shading correction data table generator 103.

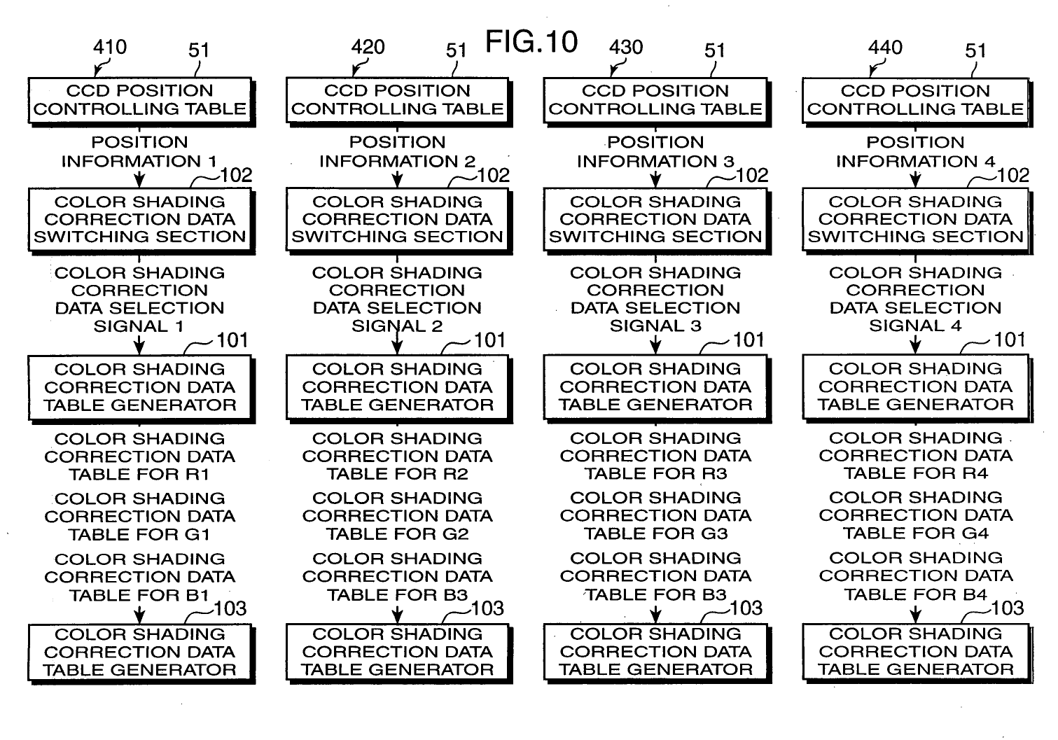

Specifically, in cases shown by 410 to 440 in FIG. 10, pieces of position information 1 to 4 corresponding to the four detections of the position information during each exposure period are sent from the CCD position controlling table 51 (position detector 520) to the color shading correction data setting section 102 every time the position information is detected. The color shading correction data setting section 102 determines the comparison point closest to the relative position of the optical axis and the CCD array 21 in accordance with the respective received pieces of the position information 1 to 4 and the information on the saved arrangement pattern 210. Then, signals for selecting the color shading correction data of the respective colors R, G, B corresponding to this comparison point, that is, color shading correction data selection signals 1 to 4, are sent to the color shading correction data table memory 101, and the color shading correction data tables of the respective colors R, G, B corresponding to this comparison point, that is, color shading correction data tables 1 to 4 for R, G, B, are read from the color shading correction data table memory 101 and transferred to the color shading correction data table generator 103.

The color shading correction data table generator 103 successively saves the color shading correction data tables transferred four times upon the detection of the four pieces of the position information, and applies the averaging and the inner interpolation to the gain data (reference gain data) written in these color shading correction data tables to generate the execution color shading correction data. As the color shading correction is applied to the image data sent from the CCD array 21 to the image processor 42 via the A/D converter 41, the color information of the image data from the image processor 42 is received and the color shading correction data (respective gain data for multiplying the respective pixels) are successively sent to the image processor 42 at specified timings. In the image processor 42, the image data are multiplied by the gain data to apply the color shading correction, and the image data having the color shading corrected are recorded in the recording medium M or the like. The color shading correction data tables corresponding to the pieces of the position information 1 to 4 (these are, for example, assumed to be the pieces of the position information A-1 to A-4 of FIG. 9) saved in the aforementioned color shading correction data table generator 103 may be successively replaced by the color shading correction data tables corresponding to the pieces of the position information 1 to 4 by the next exposure (pieces of the position information B-1 to B-4 of FIG. 9).

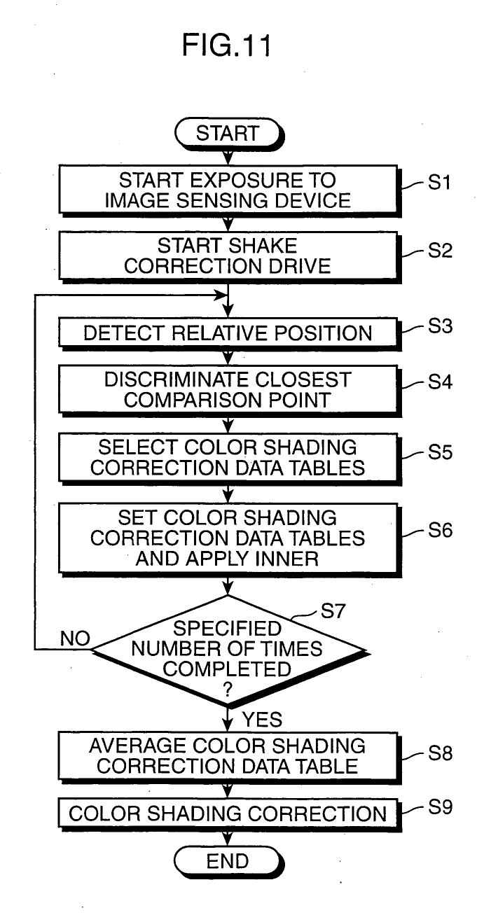

Next, the color shading correcting operation is described. FIG. 11 is a flowchart showing one exemplary operation concerning the color shading correction of the electronic camera 1 according to this embodiment. First, exposure to the CCD array 21 (photographing) is started (Step S1), and the shake correcting unit 50 starts the shake correcting drive (Step S2). Subsequently, the relative position of the optical axis of the taking lens 3 and the CCD array 21 is detected by the CCD position controlling table 51 (position detector 520) (Step S3). Then, the color shading correction data setting section 102 discriminates the comparison point closest to this relative position in accordance with the relative position information and the information on the saved arrangement pattern 210 (Step S4). The color shading correction data tables of the respective colors R, G, B corresponding to the discriminated comparison point are selected and read from the color shading correction data table memory 101 (Step S5). The read color shading correction data tables of the respective colors are transferred to and saved or set in the color shading correction data table generator 103 (Step S6).

Unless the operation of setting the color shading correction data tables has been carried out a specified number of times during one exposure period in Step S6, i.e., unless the position information has been detected a specified number of times (here, four times to obtain the pieces of the position information 1 to 4) during one exposure period shown in FIGS. 9 and 10 (NO in Step S7), this routine returns to Step S3 to detect the next position information (relative position). If the operation of setting the color shading correction data tables has been carried out the specified number of times (four times) during one exposure period in Step S6 (YES in Step S7), the color shading correction data generator 103 averages the reference gain data written in the four color shading correction data tables for the respective colors R, G, B (color shading correction data tables 1 to 4 for R, color shading correction data tables 1 to 4 for G and color shading correction data tables 1 to 4 for B shown in FIG. 10) saved in the color shading correction data setting section 102 in correspondence with the four pieces of the position information, and carries out the inner interpolation using the reference gain data after the averaging (Step S8). Then, the image processor 42 successively multiplies the respective pixel data (pixel data of the respective colors) of the photographed image by the respective gain data (gain values) of the execution color shading correction data tables of the respective colors R, G, B generated by the averaging and the inner interpolation (Step S9).

As described above, according to the electronic camera 1 of this embodiment, even if the image sensor is moved in accordance with a displacement of the optical axis by the shake correction by the shake correcting unit 50 to change or displace the relative position of the optical axis of the taking lens 3 and the CCD array 21, the changed relative position and the respective comparison points of the arrangement pattern 210 are compared at any time, the color shading correction information pattern to be used, e.g., color shading correction information set as a default at the reference position such as the reference point 204, is switched or set to the color shading correction information pattern of the respective colors R, G, B corresponding to the relative position, and the color shading is corrected in accordance with the color shading correction information pattern of the respective colors R, G, B. Thus, corrections (color shading corrections) can be carried out to asymmetric and complicated color shading, and the color shading corrections can be precisely carried out even during the photographing operation in the case of correcting the shake such as the camera shake.

Further, since the relative position is detected at least once during one exposure of the CCD array 21 by the CCD position controlling table 51 (position detector 520), the color shading of the photographed image that changes every moment as each exposure period of the CCD array 21 elapses can be detected by detecting the relative position (at least once) during each exposure period, and this detection can be securely reflected on the color corrections carried out to the color shading. If the relative position is detected a plurality of times during each exposure period, a more precise color shading correction can be carried out, for example, by using an average of a plurality of pieces of detected information.

The respective comparison points of the arrangement pattern 210 (220, 230) on the assumed sensor surface 202 are radially (on straight lines spread out in eight directions shown in FIG. 6, in sixteen directions shown in FIGS. 12 and 13) arranged from the reference point 204 as a reference of the relative position of the optical axis and the CCD array 21 toward the peripheral sides. This arrangement conforms to an actual change or displacement of the relative position to radially move from the reference point 204 toward the peripheral side, and the position of the comparison point close to the relative position can be efficiently detected by the simple arrangement pattern 210 (or arrangement pattern 220, 230).

Further, the respective comparison points are arranged in the arrangement pattern 220 (230) such that the arrangement density of the comparison points in the specified range near the reference point 204 is larger than or equal to that of the comparison points in the peripheral area. This can prevent the comparison points from being more spaced apart as they are more distanced from the reference point 204 (center area) toward the peripheral sides to result in a rough (low precision) color shading correction, and enables a color shading correction to be precisely carried out to such color shading that the closer to the peripheral area, the larger the color shading amount changes or the steeper the gain curve, i.e., that more comparison points (color shading correction information patterns) are required for the peripheral area.

In the arrangement pattern 230, no comparison point is arranged in the specified range (comparison-point free area 231) including the reference point 204 as an area of the photographed image where no color shading correction is carried out. Thus, less arrangement pattern information is required and a memory capacity for storing it can be reduced. Further, an efficient color shading correction can be carried out in conformity with a difference in the color shading of the respective parts of the photographed image, e.g., the color shading correction is carried out in the area which is distanced from the comparison-point free area 231 (center area) and where the influence of the color shading is not negligible while no color shading correction is carried out in the specified range in the center where the influence of the color shading is thought to be negligible.

The following modifications may be appreciated:

(A) Although the color shading correction information patterns (data tables) are saved in the color shading correction data table memory 101 of the camera main body 2 in the foregoing embodiment, the color shading correction data tables may be saved in a place other than the camera main body 2 and the color shading corrections may be carried out using them if necessary. Specifically, a specified memory may be, for example, built in the taking lens, and at least a plurality of color shading correction data tables corresponding to a relative position relationship with the CCD array 21 may be saved in this internal memory. Upon detecting that this taking lens is connected with the camera main body 2, the main control unit 80 copies the color shading correction data tables saved in the internal memory in a memory for the color shading correction data tables (corresponding to the color shading correction data table memory 101). During the drive to correct the shake, the color shading corrections may be carried out using the copied color shading correction data tables similar to the foregoing embodiment. In this way, the color shading corrections in a lens-exchanging type camera can be easily realized by letting the taking lens possess the color shading correction data tables peculiar to this lens.

(B) Although the color shading corrections in the lens-interchanging type camera are realized by providing the taking lens 3 with the internal memory in which the color shading correction data tables are saved in the foregoing modification (A), such color shading corrections may be realized by saving color shading correction data tables different depending on the taking lenses in the camera main body 2, discriminating the type of the taking lens connected when the taking lens is connected, and using the color shading correction data tables suited to the discriminated taking lens.

(C) Although the color shading correction processing is carried out in the electronic camera 1 in the above respective embodiments, the color shading correction processing may be carried out in an information processing apparatus (or system) such as a personal computer (PC). Specifically, upon recording a photographed image obtained by the CCD array 21 in the image memory 110 or the recording medium M, the position information detected during each exposure period, the type of the taking lens and the like information are recorded as subsidiary information. On the other hand, a program code of software capable of image processing including the color shading correction processing and a storage medium storing the color shading correction data tables are supplied to this information processing apparatus (system). In this way, the subsidiary information is transmitted together with the photographed image to the information processing apparatus, for example, via Internet, and the color shading correction processing is carried out using the color shading correction data tables suited to this electronic camera has the taking lens in accordance with the subsidiary information in the information processing apparatus.

(D) The gain data written in the color shading correction data tables may be gain data for all the pixels of the photographed image instead of being reference gain data (gain data at the corner pixels of the blocks of FIG. 7). In this case, a larger capacity of the color shading correction data table memory 101 is necessary than in the case of storing only the reference gain data, but the processing speed can be increased because the inner interpolation is not necessary.

(E) Although no color shading correction is carried out in the comparison-point free area 231 in the arrangement pattern 230 in the foregoing embodiments, color shading corrections set for this area may be carried out without setting the color shading correction data tables corresponding to a change of the relative position.

(F) Although the reference gain data in each block shown in FIG. 7 are set at the pixel positions at the corners (four positions) in the foregoing embodiments, the reference gain data may be set at pixel points of arbitrary positions (e.g., middle positions) of the respective sides or boundary lines of each block, and the number of the set positions may not be four. Further, the reference gain data in each block may not be set on the respective sides, and may be set at pixel points inside each block. In this case, the gain values other than the reference gain data may be calculated not only by the inner interpolation, but also by an outer interpolation or another interpolating method. The blocks dividing the screen 300 may not take a quadratic shape such as a rectangular shape or a square shape, and may take various other shapes such as a triangular shape and a right hexagonal shape. Further, the screen 300 may be divided by a combination of variously shaped blocks.

(G) Although the color shading correction data tables are prepared only for the relative position relationship of the taking lens 3 and the CCD array 21 in the foregoing embodiments, they may be generated also in consideration of photographing conditions influential to the color shading such as a zoomed position, an aperture amount, and a focusing position in addition to this relative position relationship. In this case, an amount of the data tables is increased, but a more precise color shading correction can be carried out.

As described above, an inventive image taking apparatus having a shake correcting function for correcting a shake during the photographing and a color shading correcting function for correcting color shadings of colors R, G, B in a photographed image, comprising an image sensor for obtaining the photographed image by being exposed to an object light from a taking lens; a shake corrector for correcting a displacement of an optical axis of the taking lens and the image sensor caused by the shake by moving the image sensor relative to the optical axis; a position detector for detecting a relative position between the optical axis and the image sensor as a result of the movement; an arrangement pattern storage device for storing an arrangement pattern of comparison points to be compared with the relative position beforehand; a correction information storage device for storing color shading correction information patterns used for color shading corrections of the respective colors at the respective comparison points of the arrangement pattern beforehand; a correction information setter for comparing the relative position detected by the position detector with the comparison points in the arrangement pattern and setting a color shading correction information pattern at the comparison point close to the relative position; and a color shading corrector for carrying out the color shading corrections to the photographed image in accordance with the newly set color shading correction information pattern.

With this construction, the photographed image is obtained by exposing the image sensor to the object light from the taking lens, the displacement of the optical axis of the taking lens and the image sensor resulting from the shake is corrected by moving the image sensor by the shake corrector, and the relative position of the optical axis and the image sensor as a result of this movement is detected by the position detector. The arrangement pattern of the comparison points to be compared with the relative position is stored beforehand in the arrangement pattern storage device, and the color shading correction information patterns used to carry out the color shading corrections to the respective colors at the respective comparison points of the arrangement pattern are stored beforehand in the correction information storage device. The relative position detected by the position detector is compared with the comparison points of the arrangement pattern and the color shading correction information pattern to be used is switched from the one set, for example, as a default to the one at the comparison point close to the relative position by the correction information setter. The color shading corrections are carried out to the photographed image in accordance with the newly set color shading correction information pattern by the color shading corrector.

In this way, even if the image sensor is moved in accordance with the displacement of the optical axis by the shake correction to change the relative position of the optical axis of the taking lens and the image sensor, the changing relative position is compared with the respective comparison points of the arrangement pattern at any time, the color shading correction information pattern to be used is switched to the one for the respective colors at the comparison point corresponding to or close to the relative position, and the color shading corrections are carried out in accordance with the color shading correction information patterns of the respective colors R, G, B. Thus, asymmetric and complicated color shading can be corrected, and the color shading correction can be precisely carried out during the photographing in the case of correcting a shake such as a camera shake.

Preferably, the position detector may detect the relative position at least once during one exposure period of the image sensor. With this construction, since the relative position is detected at least once during one exposure period of the image sensor by the position detector, the color shading of the photographed image changing with time can be detected as each exposure period of the image sensor elapses by the detection of the relative position at least once during each exposure period and can be securely reflected on the color correction to this color shading. If the relative position is detected by a plurality of times during each exposure period, a more precise color shading correction can be carried out, for example, by using an average of a plurality of pieces of the detected information.

Preferably, the respective comparison points may be radially arranged at specified intervals from a specified reference position as a reference of the relative position of the optical axis and the image sensor toward peripheral sides. With this construction, the position of the comparison point close to the relative position can be efficiently detected by a simple arrangement pattern in conformity with an actual change of the relative position to radially move from the reference position toward the peripheral side.

Preferably, the respective comparison points may be arranged such that the arrangement density of the comparison points in a peripheral area is larger than or equal to that of the comparison points in a specified range near the reference position. With this construction, there can be prevented a rough color shading correction resulting from the longer distances between the comparison points as they are more distanced from the reference position or center area toward the peripheral sides, and a color shading correction can be precisely carried out to such color shading that the closer to the peripheral area, the larger the color shading amount change, the steeper the gain curve, i.e., the more comparison points (more color shading correction information patterns) are required for the peripheral area.

Preferably, no comparison point may be arranged in a specified range including the reference position, which range is an area of the photographed image where no color shading correction is carried out. With this construction, less arrangement pattern is required and a memory capacity to save it can be reduced. Further, the color shading correction is carried out in the peripheral area which is distanced from the specified range or center area including the reference position and where the influence of the color shading is not negligible, whereas no color shading correction is carried out in the specified range in the center area where the influence of the color shading is thought to be negligible. Therefore, such an efficient color shading correction in conformity with color shading differences in the respective parts of the photographed image can be carried out.

Although the present invention has been fully described by way of example with reference to the accompanied drawings, it is to be understood that various changes and modifications will be apparent to those skilled in the art. Therefore, unless otherwise such changes and modifications depart from the scope of the present invention hereinafter defined, they should be construed as being included therein.

What is claimed is:

1. An image taking apparatus, comprising:
a taking lens which passes a light image of an object;
an image sensor which is exposed to the light image passed through the taking lens to obtain a photographed image;
a shake corrector which moves the image sensor relative to an optical axis of the taking lens to correct a displacement of the optical axis of the taking lens against the image sensor caused by a shake;
a position detector which detects a relative position between the optical axis and the image sensor as a result of the movement;
an arrangement pattern storage device which stores an arrangement pattern of comparison points to be compared with the relative position beforehand;
a correction information storage device which stores color shading correction information patterns used for color shading corrections of colors R, G, B in the photographed image at respective comparison points of the arrangement pattern beforehand;
a correction information setter which compares the relative position detected by the position detector with the comparison points in the arrangement pattern, and set a color shading correction information pattern at the comparison point close to the relative position; and
a color shading corrector which carries out color shading corrections to the photographed image in accordance with the newly set color shading correction information pattern.

2. An image taking apparatus according to claim 1, wherein the position detector detects the relative position at least once during one exposure period of the image sensor.

3. An image taking apparatus according to claim 2, wherein the respective comparison points are radially arranged at specified intervals from a specified reference position as a reference of the relative position of the optical axis and the image sensor toward peripheral sides.

4. An image taking apparatus according to claim 3, wherein the respective comparison points are arranged such that the arrangement density of the comparison points in a peripheral area is larger than or equal to that of the comparison points in a specified range near the reference position.

5. An image taking apparatus according to claim 4, wherein no comparison point is arranged in a specified range including the reference position, which range is an area of the photographed image where no color shading correction is carried out.

6. An image taking apparatus according to claim 3, wherein no comparison point is arranged in a specified range including the reference position, which range is an area of the photographed image where no color shading correction is carried out.

7. An image taking apparatus according to claim 1, wherein the respective comparison points are radially arranged at specified intervals from a specified reference position as a reference of the relative position of the optical axis and the image sensor toward peripheral sides.

8. An image taking apparatus, comprising:
a taking lens which passes a light image of an object;
an image sensor which is exposed to the light image passed through the taking lens to obtain a photographed image;
a shake corrector which moves the image sensor relative to an optical axis of the taking lens to correct a displacement of the optical axis of the taking lens against the image sensor caused by a shake;
a position detector which detects a relative position between the optical axis and the image sensor as a result of the movement;
a storage device which stores color shading correction information patterns used for color shading corrections of colors R, G, B in the photographed image for each of comparison points to be compared with the relative position, the comparison points being arranged in a predetermined pattern; and
a color shading corrector which sets a color shading correction information pattern in accordance with the relative position detected by the position detector to carry out the color shading correction to the photographed image in accordance with the set color shading correction information pattern, when the shake corrector is put into operation.

9. An image taking apparatus according to claim 8, wherein the position detector detects the relative position at least once during one exposure period of the image sensor.

10. An image taking apparatus according to claim 9, wherein the respective comparison points are radially arranged at specified intervals from a specified reference position as a reference of the relative position of the optical axis and the image sensor toward peripheral sides.

11. An image taking apparatus according to claim 10, wherein the respective comparison points are arranged such that the arrangement density of the comparison points in a peripheral area is larger than or equal to that of the comparison points in a specified range near the reference position.

12. An image taking apparatus according to claim 11, wherein no comparison point is arranged in a specified range including the reference position, which range is an area of the photographed image where no color shading correction is carried out.

13. An image taking apparatus, comprising:
a taking lens which passes a light image of an object;
an image sensor which is exposed to the light image passed through the taking lens to obtain a photographed image;
a shake corrector which moves the image sensor relative to an optical axis of the taking lens to correct a displacement of the optical axis of the taking lens against the image sensor caused by a shake;
a position detector which detects a relative position between the optical axis and the image sensor as a result of the movement;
a storage device which stores color shading correction information patterns used for color shading corrections of colors R, G, B in the photographed image; and
a color shading corrector which carries out color shading corrections to the photographed image in accordance with the relative position detected by the position detector when the shake corrector is put into operation.

14. An image taking apparatus according to claim 13, wherein the position detector detects the relative position at least once during one exposure period of the image sensor.

15. An image taking apparatus according to claim 14, wherein the respective comparison points are radially arranged at specified intervals from a specified reference position as a reference of the relative position of the optical axis and the image sensor toward peripheral sides.

16. An image taking apparatus according to claim 15, wherein the respective comparison points are arranged such that the arrangement density of the comparison points in a peripheral area is larger than or equal to that of the comparison points in a specified range near the reference position.

17. An image taking apparatus according to claim 16, wherein no comparison point is arranged in a specified range including the reference position, which range is an area of the photographed image where no color shading correction is carried out.
